(19) United States
(12) Patent Application Publication
(10) Pub. No.: US 2012/0262309 A1
(43) Pub. Date: Oct. 18, 2012

(54) PARTICULATE BARRIER FOR KEYBOARD DISPLAY

(75) Inventor: Glen C. Larsen, Issaquah, WA (US)

(73) Assignee: MICROSOFT CORPORATION, Redmond, WA (US)

(21) Appl. No.: 13/086,940

(22) Filed: Apr. 14, 2011

(51) Int. Cl. H03M 11/00

(52) U.S. Cl. 341/22

(57) ABSTRACT

This disclosure provides for a computer peripheral having displayable output in addition to keyboard-type input functionality. A plurality of keycaps are situated over a display device, and each keycap is movable downward and upward relative to the display device. Associated with each of the keycaps is a display region on the display device. The display region produces imagery which is viewable through transparent portions of the keycap. For each of the keycaps, a particulate barrier is provided to prevent particulate from entering into the display regions associated with the keycaps.

### BACKGROUND

Computer peripherals are continually being refined to expand functionality and provide quality user experiences. One area of improvement has been to provide peripheral devices that combine keyboard-type input functionality with the ability to display output to the user. One approach involves combining input and output capability in a peripheral device through use of a virtual keyboard on a touch interactive display. In this case, the display capability is provided directly on the keys: each key typically is displayed by the touch interactive device with a legend or symbol that indicates its function. The virtual keyboard approach has many benefits, including the ability to dynamically change the display for each key. Interactive touch displays are often less desirable, however, from a pure input standpoint. Specifically, touch displays do not provide mechanical key depression or tactile feedback, which can provide a more responsive and agreeable typing experience.

### SUMMARY

This disclosure provides for a computer peripheral in which depressible keys are situated over a display device. The display device produces imagery which can be viewed through the keys, due to the keycaps being at least partially transparent. By looking through the keycap (e.g., through a central viewing window), the user is able to see imagery produced by a display region on the display device which is associated with the key and keycap. If allowed to enter into the display region, dust and other particulate matter can compromise the display aspect of the computer peripheral. Accordingly, the examples herein include a particulate barrier configured to prevent entry of particulate matter from an exterior of the computer peripheral into the display regions associated with the keys/keycaps.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to implementations that solve any or all disadvantages noted in any part of this disclosure.

### BRIEF DESCRIPTION OF THE DRAWINGS

FIG. 1 depicts an exemplary computing system including an exploded view of a computer peripheral that provides displayable output which is viewable through physically-depressible keys situated over a display device.

FIG. 2 is a non-exploded view of the computer peripheral of FIG. 1.

FIG. 3 illustrates an example of the output display capability that may be employed in connection with the computer peripheral of FIGS. 1 and 2.

FIG. 4 depicts an exemplary keycap of the computer peripheral of FIGS. 1 and 2. In the figure, the keycap is situated over an associated display region of a display device underlying the keycap.

FIGS. 5, 6 and 7 show embodiments of a particulate barrier that may be used in connection with the keycaps of the computer peripheral of FIGS. 1 and 2.

FIG. 8 shows another embodiment of a particulate barrier that may be used in connection with the keycaps of the computer peripheral of FIGS. 1 and 2.

FIG. 9 shows yet another embodiment of a particulate barrier that may be used in connection with the keycaps of the computer peripheral of FIGS. 1 and 2.

### DETAILED DESCRIPTION

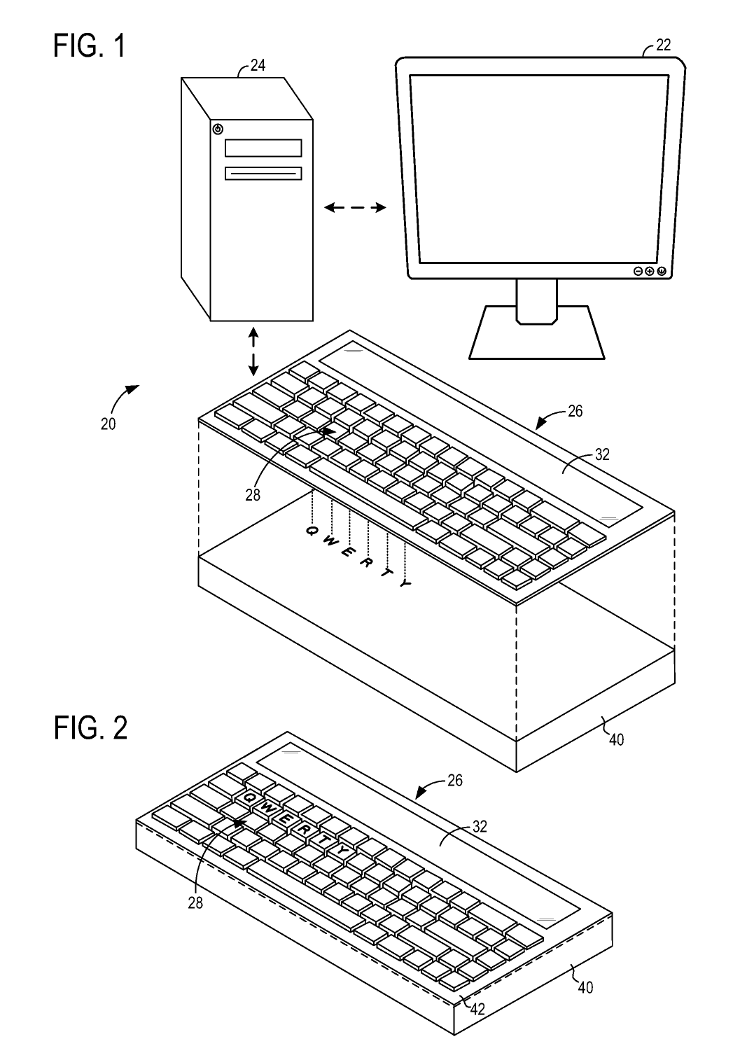

This disclosure will now be discussed in detail with reference to FIGS. 1-9. It will be appreciated that some figures contain common features and are therefore described with common reference numbers consistently throughout this disclosure. To avoid redundancy, such features will not be discussed repeatedly. Further, it will be appreciated that the figures are provided by way of example and are not meant to be limiting in any way. Some features of the figures may not necessarily be drawn to scale, and as such, some features may be exaggerated or simplified for illustrative purposes. This is for simplicity of understanding and not for technical accuracy.

This disclosure is directed to a computer peripheral having a keyboard assembly situated over a display device. The keys of the keyboard assembly are physically/mechanically depressible, such that the keycaps are able to move reciprocally downward and upward relative to the display device.

More particularly, each keycap is able to move up and down relative to a display region on the display device which is associated with the keycap. The keycap is at least partially transparent to allow for through-keycap (see-through) viewing of images produced by the display region associated with the keycap. Because the display device provides viewable imagery, it is desirable to protect the display regions from dust or other particulate matter. Accordingly, the embodiments herein provide for various particulate barriers to prevent particulate entry and associated negative impact on the imagery viewable through the keys.

FIG. 1 depicts an exemplary computing system 20 comprising a display monitor 22, a component enclosure 24 (e.g., containing a processor, memory, hard drive, etc.), and a computer peripheral 26 shown in an exploded state. FIG. 2 provides an additional view of computer peripheral 26 (non-exploded) and exemplary components that may be used in its construction. As will be described in various examples, computer peripheral 26 may be implemented to provide displayable output in addition to keyboard-type input functionality.

In some examples, displayable output of the computer peripheral is provided from a liquid crystal display (LCD) or other display device, and is viewed through the plurality of keys of a keyboard assembly that is disposed over the top of the display device. Individual keys may be implemented via a keycap and a mechanical understructure that guides reciprocating up-and-down movement of the keycap relative to the underlying display device.

The terms “input” and “output” will be used in this description in reference to the keyboard functionality of the exemplary computer peripherals. When used in connection with a keyboard key, the term “input” will generally refer to the input signal that is provided by the peripheral upon activation of the key. “Output” will generally refer to the display provided for a key, such as the displayed legend, icon or symbol that indicates the function of the key.

As indicated by the “Q”, “W”, “E”, “R”, “T”, “Y”, etc., on keys 28 (FIGS. 1 and 2), it will often be desirable that computer peripheral 26 be configured to provide conventional alphanumeric input capability. To simplify the illustration, many keys of FIGS. 1 and 2 are shown without indicia, though it will be appreciated that a label or display will often be included for each key. Furthermore, in addition to or instead of the well-known “QWERTY” formulation, the keys 28 of the keyboard may be variously configured to provide other inputs. Keys may be assigned, for example, to provide functionality for various languages and alphabets, and/or to activate other input commands for controlling computing system 20. In some implementations, the key functions may change dynamically, for example in response to the changing operational context of a software application running on computing system 20. For example, upon pressing of an “ALT” key, the key that otherwise is used to enter the letter “F” might instead result in activation of a “File” menu in a software application. Generally, it should be understood that the keys in the present examples may be selectively depressed to produce any type of input signal for controlling a computer.

Computer peripheral 26 can provide a wide variety of displayable output. In some examples, the computer peripheral causes a display of viewable output on or near the individual keys 28 to indicate key function. This can be seen in FIGS. 1 and 2, where instead of keys with letters painted, printed or etched onto the keycap surface, a display mechanism (e.g., a liquid crystal display (LCD) device situated under the keys) is used to indicate the “Q”, “W”, etc., functions of the keys. This dynamic and programmable display capability facilitates potential use of the computer peripheral 26 in a variety of different ways. For example, the English-based keyboard described above could be alternately mapped to provide letters in alphabetical order instead of the conventional “QWERTY” formulation, and the display for each key could then be easily changed to reflect the different key assignments.

The display capability contemplated herein may be used to provide any type of viewable output to the user of computing system 20, and is not limited to alphabets, letters, numbers, symbols, etc. As an alternative to the above examples, images may be displayed in a manner that is not necessarily associated in a spatial sense with an individual key. An image might be presented, for example, in a region of the keyboard that spans multiple keys. The imagery provided need not be associated with the input functionality of the keyboard. Images might be provided, for example, for aesthetic purposes, to personalize the user experience, or to provide other types of output. Indeed, the present disclosure encompasses display output for any purpose. Also, in addition to display provided on or near keys 28, display functionality may be provided in other areas, for example in an area 32 located above keys 28. Still further, area 32 or other portions of computer peripheral 26 may be provided with touch or gesture-based interactivity in addition to the keyboard-type input provided by keys 28. For example, area 32 may be implemented as an interactive touchscreen display, via capacitance-based technology, resistive-based technology or other suitable methods.

Turning now to FIG. 2, computer peripheral 26 may include a display device 40 and a keyboard assembly 42 disposed over and coupled with the display device. Keyboard assembly 42 may be at least partially transparent, and may be otherwise configured to allow a user to view images produced by the display device through the keyboard assembly. In one embodiment, for example, each keycap has a central transparent portion, and a mechanical understructure is provided to guide and/or constrain reciprocating movement of the keycap toward and away from the display device. The mechanical understructure may be disposed on the periphery of the key away from a central portion of the keycap, to facilitate through-key viewing of images produced by the display device.

As indicated briefly above, one type of suitable display device is an LCD device. This is non-limiting, however, and it should be appreciated that the keyboard assembly may be coupled with a variety of other display types.

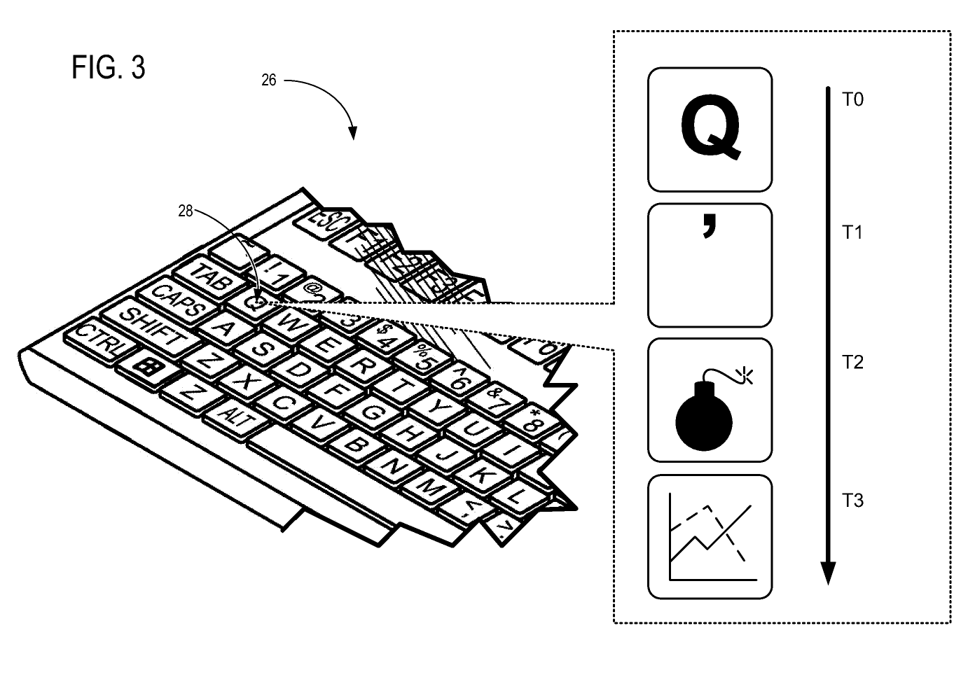

FIG. 3 provides further illustration of how the display capability of computer peripheral 26 may be employed in connection with an individual key 28. In particular, as shown respectively at times T0, T1, T2, etc., the display output associated with key 28 may be changed, for example to reflect the input command produced by depressing the key. However, as previously mentioned, the viewable output provided by the computer peripheral may take forms other than displays associated with individual keys and their input functionality.

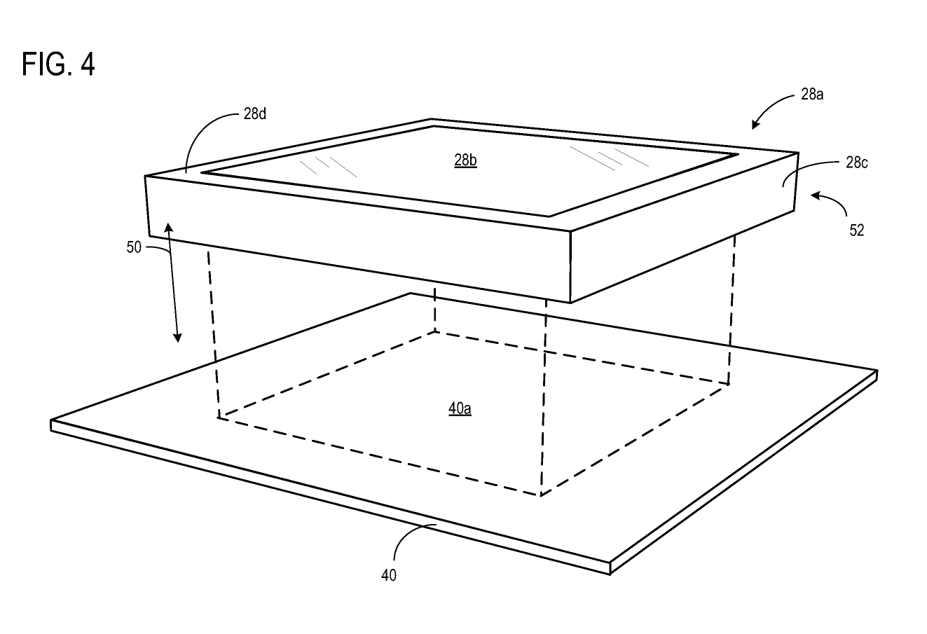

FIG. 4 depicts an exemplary keycap 28a. As indicated at 50, keycap 28a is reciprocally movable up and down relative to an associated display region 40a on display device 40. Keycap 28a includes a central viewing window 28b aligned with display region 40a to permit a user to view images produced by the display region through the keycap.

Keycap 28a also includes an outer border 28c extending around the periphery of the keycap. Together with outer borders of adjacent keycaps (not shown), outer border 28c defines an ambient entrance (indicated generally at 52). Dust and other particulate matter can potentially reach display region 40a via entry through the ambient entrance defined around the key. Stated another way, particulate can potentially reach the display region by entering between the keycaps from an exterior of the computer peripheral.

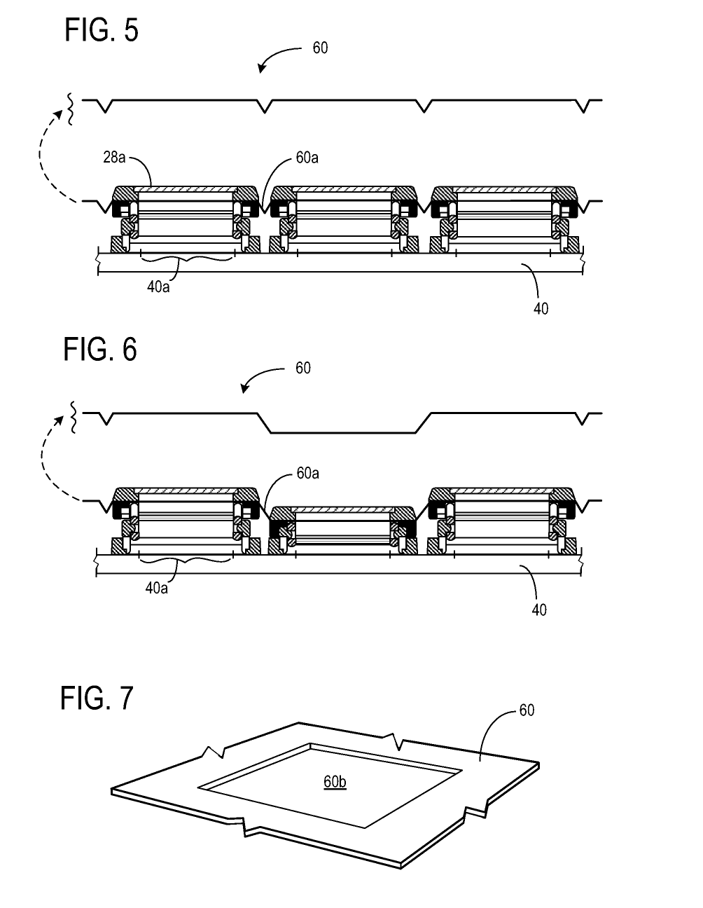

In some examples, one or more particulate barriers are positioned below upward-facing surfaces (e.g., surface 28d) of the keycaps to thereby prevent or block entry of particulate. These barriers may be interposed between the ambient entrance(s) defined around the keycaps and the associated display regions of the keycaps, so as to prevent particulate entry through the areas between the keys. Example particulate barriers will be described with specific reference to FIGS. 5 through 9. These examples will all be described in connection with a keycap. The keycaps in these examples: (1) are movable up and down relative to an associated display region; (2) are at least partially transparent to permit through-keycap viewing; and (3) include borders defining the above-described ambient entrance(s), which can potentially permit entry of particulate from an exterior of the device between the keycaps.

FIGS. 5, 6 and 7 depict a particulate barrier in the form of barrier sheet 60. Barrier sheet 60 is substantially parallel to the surface of display device 40, and extends horizontally through keycaps 28a. Barrier sheet 60 is interposed between the ambient entrances of the keycaps and the associated display regions 40a, and is configured to block particulate from reaching the display regions via entry from the exterior of the computer peripheral through the areas between the keys. In particular, portions 60a serve to block entry of particulate between the keys.

The barrier sheet may be formed from a variety of materials. Regardless of the specific material, the material is flexible or otherwise deformable to allow for the upward and downward movement of the key. This is seen with reference to FIGS. 5 and 6, which respectively show the middle keycap in a non-depressed and depressed position relative to the underlying display device 40.

In some embodiments, barrier sheet 60 may be an uninterrupted expanse situated over the display device. In these examples, the sheet is formed from a transparent material, so as to not interfere with viewing of images produced by the display regions 40a. In other examples, such as the embodiment shown in FIG. 7, barrier sheet 60 may be provided with holes 60b that are aligned with the keycap viewing windows and corresponding display regions 40a on the display device.

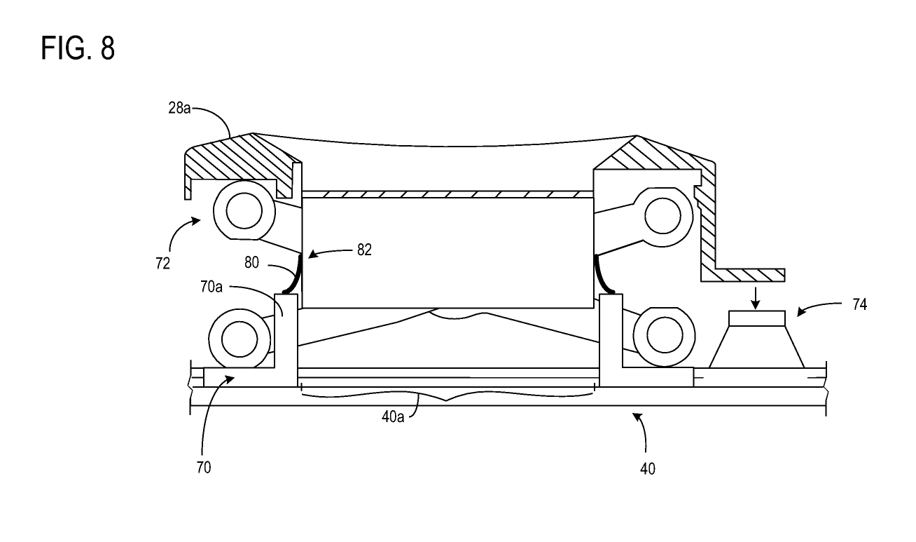

Referring now to FIG. 8, keycap 28a is coupled to a base structure 70 via a mechanical understructure in the form of scissors assembly 72. The base structure is disposed over display device 40. In some examples, the base structure includes holes aligned with the display regions (e.g., display region 40a), to permit through-keycap viewing of images from the display device. In such a case, the base structure may or may not be transparent. In other examples, holes are not included and the base structure accordingly is transparent.

In addition to providing a base for supporting and/or connecting to the mechanical understructure, the base structure may include or be adjacent to a layer of electrical traces wherein the electrical traces activate input signals in response to key depression. Electrical traces may be employed in connection with any of the examples herein to provide input signals. Alternatively, input actuation may be detected through use of touch sensing or near-touching sensing, as provided by display device 40 or other components of the computing system. As another example, the computing system may employ vision/optical technologies to detect depression of keys. Any suitable method of input detection may be employed, in addition to or instead of these examples.

The mechanical understructure is configured to guide and/or constrain reciprocal upward and downward movement of the keycap. A variety of mechanical understructures can be employed in addition to or instead of a scissors assembly. Further examples include hinges, springs, vertical guides, corresponding telescopically engaged structures on the keycap and base structure, etc. Also, various methods may be employed to provide a desired tactile feel when keys are depressed. FIG. 8 shows a non-limiting example of a resiliently-deformable tactile feedback dome 74 that provides a “snapping” feel.

The example of FIG. 8 includes a particulate barrier in the form of an upwardly-extending portion 70a of base structure 70. This forms a wall that surrounds display region 40a, such that it is interposed between the display region and the ambient entrances around the key. Accordingly, portion 70a is situated so as to block particulate which may enter between the keys.

The particulate barrier in this and other examples herein may further include a wiper structure surrounding the display region. When employed, the wiper structure is biased to urge against and engage a wiped surface. In the example of FIG. 8, wiper structure 80 is connected to portion 70a of base structure 70, and is biased to urge against a wiped surface 82 of keycap 28a. Alternatively, the wiper structure may be connected to the key/keycap, and biased to urge against a wiped surface on the base structure.

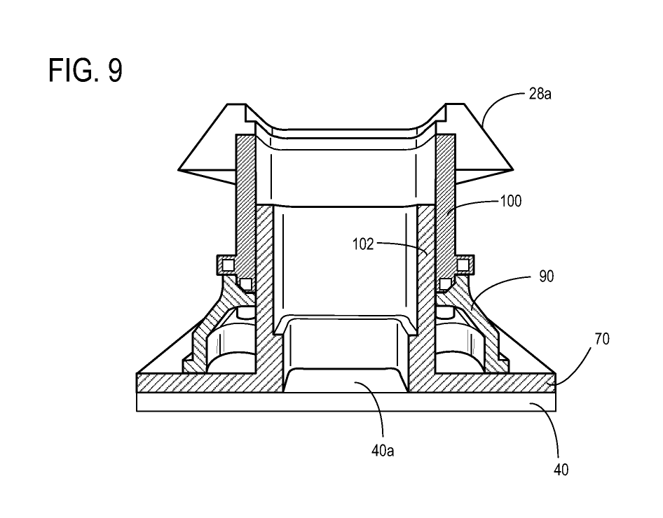

FIG. 9 provides another example of a particulate barrier interposed between an ambient entrance of a keycap and a display region, so as to block particulate from entering between keys. In this example, the particulate barrier is a seal 90 that surrounds display region 40a of display device 40. In this example, the seal is coupled between keycap 28a and base structure 70. More particularly, the seal is connected to a downwardly-extending wall 100 of the keycap that telescopically engages with an upwardly-extending wall 102 of the base structure. Seal 90 may also be formed from a resilient material that deforms elastically when the key is depressed. The elastic deformation can produce a desired tactile feel for the key, as well as providing a force to return the key to an un-depressed state when released by the user.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. As such, various acts illustrated may be performed in the sequence illustrated, in other sequences, in parallel, or in some cases omitted. Likewise, the order of the above-described processes may be changed.

The subject matter of the present disclosure includes all novel and nonobvious combinations and subcombinations of the various processes, systems and configurations, and other features, functions, acts, and/or properties disclosed herein, as well as any and all equivalents thereof.

1. A computer peripheral, comprising:
a display device including a plurality of display regions; and
a plurality of keycaps situated over the display device, wherein for each of the keycaps:
the keycap is reciprocally movable downward and upward relative to a display region on the display device associated with the keycap,
the keycap is at least partially see-through to permit through-keycap viewing of images produced by the display region associated with the keycap,
an ambient entrance is defined between an outer border of the keycap and outer borders of adjacent keycaps, and
a particulate barrier is interposed between the ambient entrance and the display region.

2. The computer peripheral of claim 1, wherein each of the keycaps is coupled to a base structure situated over the display device via a scissors assembly configured to guide reciprocal downward and upward movement of the keycap relative to the base structure and the display region associated with the keycap.

3. The computer peripheral of claim 2, wherein for each of the keycaps, the particulate barrier is a portion of the base structure that extends upward and surrounds the display region associated with the keycap.

4. The computer peripheral of claim 3, wherein for each of the keycaps, the particulate barrier further includes a wiper structure connected to the portion of the base structure, the wiper structure surrounding the display region associated with the keycap and being biased to urge against a wiped surface of the keycap.

5. The computer peripheral of claim 1, wherein for each of the keycaps, the particulate barrier is a wiper structure that surrounds the display region associated with the keycap and is biased to urge against a wiped surface.

6. The computer peripheral of claim 1, wherein each of the keycaps is reciprocally movable downward and upward relative to a base structure situated over the display device, the particulate barrier being a seal coupled between the keycap and the base structure, wherein the seal surrounds the display region associated with the keycap.

7. The computer peripheral of claim 6, wherein the seal deforms elastically in response to depression of the keycap toward the display device.

8. The computer peripheral of claim 6, wherein each of the keycaps includes a downwardly-extending wall that telescopically engages with an upwardly-extending wall of the base structure, the seal being connected between the downwardly-extending wall and the base structure.

9. The computer peripheral of claim 1, wherein the particulate barrier for each of the keycaps is defined by a barrier sheet extending through the keycaps substantially parallel to the display device.

10. The computer peripheral of claim 9, wherein the barrier sheet includes a plurality of holes, each of which is aligned with a corresponding one of the display regions on the display device.

11. A computer peripheral, comprising:
a display device having a plurality of display regions;
a plurality of keycaps situated over the display device that are each reciprocally movable downward and upward relative to an associated one of the display regions, each keycap being at least partially see-through to permit through-keycap viewing of images produced by the display region associated with the keycap; and
one or more particulate barriers positioned below upward-facing surfaces of the keycaps and configured to block particulate from reaching the display regions via entry between the keycaps from an exterior of the computer peripheral.

12. The computer peripheral of claim 11, wherein each of the keycaps is coupled to a base structure situated over the display device via a scissors assembly configured to guide reciprocal downward and upward movement of the keycap relative to the base structure and the display region associated with the keycap.

13. The computer peripheral of claim 12, wherein for each of the keycaps, a portion of the base structure extends upward and surrounds the display region associated with the keycap, thereby providing a particulate barrier.

14. The computer peripheral of claim 13, wherein the particulate barrier further includes a wiper structure connected to the portion of the base structure, the wiper structure surrounding the display region associated with the keycap and being biased to urge against a wiped surface of the keycap.

15. The computer peripheral of claim 11, wherein for each of the keycaps, a particulate barrier is provided in the form of a wiper structure that surrounds the display region associated with the keycap and which is biased to urge against a wiped surface.

16. The computer peripheral of claim 11, wherein each of the keycaps is reciprocally movable downward and upward relative to a base structure situated over the display device, a particulate barrier being provided for each of the keycaps in the form of a seal coupled between the keycap and the base structure, wherein the seal surrounds the display region associated with the keycap.

17. The computer peripheral of claim 11, wherein the one or more particulate barriers are defined by a barrier sheet extending through the keycaps substantially parallel to the display device.

18. The computer peripheral of claim 17, wherein the barrier sheet includes a plurality of holes, each of which is aligned with a corresponding one of the display regions on the display device.

19. A computer peripheral, comprising:
a display device including a plurality of display regions; and
a plurality of keycaps situated over the display device, wherein for each of the plurality of keycaps:
the keycap is coupled to a base structure situated over the display device via a scissors assembly configured to guide reciprocal downward and upward movement of the keycap relative to the base structure and relative to a display region on the display device associated with the keycap,
the keycap is at least partially see-through to permit through-keycap viewing of images produced by the display region associated with the keycap,
an ambient entrance is defined between an outer border of the keycap and outer borders of adjacent keycaps, and
a portion of the base structure surrounding the display region extends upward from the display device to provide a particulate barrier interposed between the ambient entrance and the display region.

20. The computer peripheral of claim 19, wherein the particulate barrier further includes a wiper structure connected to the portion of the base structure, the wiper structure surrounding the display region associated with the keycap and being biased to urge against a wiped surface of the keycap.
